(19) United States
(12) Patent Application Publication
(10) Pub. No.: US 2021/0273401 A1
(43) Pub. Date: Sep. 2, 2021

(54) PACKAGE INCLUDING PORTIONS OF A LEAD FRAME AS ELECTRICALLY CONDUCTIVE LEADS

(71) Applicant: ams Sensors Asia Pte. Ltd., Singapore (SG)

(72) Inventors: Martin Lukas Balimann, Eindhoven (NL); Harald Etschmaier, Graz (AT); Coen Tak, Eindhoven (NL); Ian Kilburn, Eindhoven (NL); Arnold Umali, Eindhoven (NL)

(21) Appl. No.: 17/259,036

(22) PCT Filed: Jul. 12, 2019
(86) PCT No.: PCT/SG2019/050342

§ 371 Date: Jan. 8, 2021

Related U.S. Application Data
(60) Provisional application No. 62/712,359, filed on Jul. 31, 2018.

(51) Int. Cl. H01S 5/02208; H01S 5/0232; H01S 5/0236; H01S 5/042; H01S 5/00; H01S 5/02234

(52) U.S. Cl. CPC H01S 5/02208; H01S 5/0232; H01S 5/02234; H01S 5/042; H01S 5/0014; H01S 5/0236

(57) ABSTRACT

The disclosure describes packages having portions of a lead frame as electrically conductive leads. The conductive leads can facilitate bringing signals acquired at the top of a package down to electrically conductive pads at the bottom of the package (or vice-versa). The techniques can be used in a range of different applications, for example, the monitoring of signals to enhance the safety of a light emitting package, as well as other applications in which a signal acquired at a top side of an package needs to be brought to conductive pads at a bottom side of the package, or to bring signals from conductive pads at the bottom side of the package to the top side of the package.

### CROSS-REFERENCE TO RELATED APPLICATION(S)

The present application claims the benefit of priority of U.S. Provisional Patent Application No. 62/712,359 filed on Jul. 31, 2018. The contents of the earlier application are incorporated here by reference in their entirety.

### FIELD OF THE DISCLOSURE

This disclosure relates to packages having portions of a lead frame as electrically conductive leads.

### BACKGROUND

New features are being added to smart phones, tablets and other portable computing devices that include technologies to record three dimensional images, sense motion and/or gestures. Digital recording methods use various types of miniature illuminators, which interact with cameras to record dynamical events in three dimensional regions. These illuminators can be of various forms and deliver different types of functions. Some illuminate a wide area with very short pulses for Light Detection and Ranging (LIDAR) type measurements recording time of flight information. Other illuminators are pulsed or continuous wave (CW), and project structured light patterns onto a scene. The digital camera records an image of the structured light pattern, and software algorithms are used to determine three-dimensional scene information from modifications in the patterned image.

One technology that is suitable for miniature illuminators is high power vertical cavity surface emitting laser (VCSEL) devices and array devices. These devices can be pulsed with very fast rise times suitable for time-of-flight applications. They are small, but produce high power laser beams with efficient electro-optic conversion. However, various optical components (e.g., an optical diffuser) can be placed in the beam path to modify the beam properties for the specific application.

The optical output power of a bare VCSEL typically can, in some cases, be so high that it may cause damage to a person's eye or skin in the event the quality of the optical component is compromised. Thus, it is important to ensure that the high power laser illuminators meet laser safety regulations when operated in the portable computing devices. For example, the illuminator may be part of an assembly that, under normal operating conditions, maintains eye-safe operation by preventing a person from getting too close to the illuminator. However, in some cases, damage (e.g., cracks) to the optical structure that modifies the output beam for safe operation, or the presence of moisture or chemical contamination on the optical structure, may result in safety hazards. Likewise, if the optical structure were to fall off or be removed, safety could be compromised.

### SUMMARY

This disclosure describes packages that can have portions of a lead frame as electrically conductive leads. The conductive leads can facilitate bringing signals acquired at the top of a package down to electrically conductive pads at the bottom of the package (or vice-versa). The techniques can be used in a range of different applications, for example, the monitoring of signals to enhance the safety of a light emitting package, as well as other applications in which a signal acquired at a top side of an package needs to be brought to conductive pads at a bottom side of the package, or to bring signals from conductive pads at the bottom side of the package to the top side of the package.

For example, in one aspect, the present disclosure describes an apparatus that includes an optical assembly including an electrically conductive structure. The apparatus also includes an electrically insulating housing including an inner chamber, a ledge to support the optical assembly over the inner chamber, and a first channel extending along an outer surface of a sidewall of the housing. A first electrically conductive lead has a first portion at least partially disposed in the first channel, a second portion bent with respect to the first portion and forming a conductive contact adjacent a bottom side of the housing opposite the optical assembly, and a third portion bent with respect to the first portion, the third portion of the first electrically conductive lead being adjacent the ledge and being in electrical contact with the electrically conductive structure.

Some implementations include one or more of the following features. For example, the first electrically conductive lead can be composed of a portion of a lead frame. In some instances, the electrically conductive structure is connected to the third portion of the first electrically conductive lead by way of a conductive pad of the electrically conductive structure of the optical assembly. The electrically conductive structure further can be connected to the third portion of the first electrically conductive lead by way of electrically conductive epoxy.

In some implementations, the apparatus includes a light source disposed within the inner chamber, and a controller electrically coupled to the conductive contact adjacent the bottom side of the housing, The controller can be operable to monitor an electrical characteristic of the electrically conductive structure, and to regulate an optical output of the light source based on the monitored electrical characteristic. In some cases, the optical assembly includes a transmissive substrate, and the electrically conductive structure includes a trace on a surface of the transmissive substrate. The electrically insulating housing can include, for example, a second channel extending along an outer surface of a sidewall of the housing. The apparatus further can include a second electrically conductive lead having a first portion at least partially disposed in the second channel, a second portion bent with respect to the first portion of the second electrically conductive lead and forming a second conductive contact adjacent the bottom side of the housing, and a third portion bent with respect to the first portion of the second electrically conductive lead, wherein the third portion of the second electrically conductive lead is adjacent the ledge and is in electrical contact with the electrically conductive structure.

In accordance with another aspect, the disclosure describes an apparatus that includes an optical assembly including an electrically conductive structure. The apparatus also includes an electrically insulating housing including an inner chamber, and a ledge to support the optical assembly over the inner chamber. A first electrically conductive lead having a first portion extends through a sidewall of the housing, with one end of the first electrically conductive forming a conductive contact adjacent a side of the housing opposite that of the optical assembly, and a second end of the first electrically conductive lead being exposed adjacent the ledge and being in electrical contact with the electrically conductive structure.

The disclosure also describes methods of fabricating the packages. For example, in one aspect, a method includes providing a lead frame, and forming an electrically insulating housing that encompasses part of the lead frame adjacent a first side of the housing. The housing defines an inner chamber, a ledge adjacent a second side of the housing opposite the first side, and a channel in an outer surface of a sidewall of the housing. The method further includes trimming a first lead of the lead frame such that one end of the first lead is free, bending the free end of the first lead, and bending the first lead toward the housing such that a first portion of the first lead fits within the channel and another portion of the first lead is adjacent the ledge. An optical assembly is placed on the ledge such that the other portion of the first lead is in electrical contact with an electrically conductive structure of the optical assembly.

Some implementations include one or more of the following features. For example, in some instances, the method includes attaching the optical assembly to the ledge using a non-conductive adhesive, and applying UV radiation to cure the non-conductive adhesive partially. The method also may include providing electrically conductive epoxy between the electrically conductive structure and the other portion of the first lead that is adjacent the ledge, and applying a thermal treatment to cure the electrically conductive epoxy and to complete curing of the non-conductive adhesive. In some cases, the optical assembly includes a transmissive substrate, and the electrically conductive structure includes a trace on a surface of the transmissive substrate.

In accordance with another aspect, a method includes attaching a mold tool to a lead frame having a bent portion, and injecting a mold compound into the mold tool to form an electrically insulating housing that defines an inner chamber and a ledge adjacent a first side of the housing. A part of the lead frame including the bent portion forms a first electrically conductive lead having a first portion extending through a sidewall of the housing. A first end of the first electrically conductive lead forms a conductive contact adjacent a second side of the housing opposite that of the first side, and a second end of the first electrically conductive lead is exposed adjacent the ledge. The method includes placing an optical assembly on the ledge such that the second end of the first lead is in electrical contact with an electrically conductive structure of the optical assembly.

Other aspects, features and advantages will be readily apparent from the following detailed description, the accompanying drawings and the claims.

### BRIEF DESCRIPTION OF THE DRAWINGS

FIG. 1A illustrates an example of an optical assembly including a capacitive electrically conductive structure.

FIG. 1B illustrates an example of an optical assembly including a resistive electrically conductive structure.

FIG. 2 is a block diagram showing an example of a circuit for monitoring an electrically conductive structure and controlling a light source.

FIG. 3 is an exploded view of an optoelectronic package.

FIG. 4 illustrates features of the optoelectronic package of FIG. 3 (with the optical assembly omitted).

FIG. 5 is a cross-sectional view of FIG. 4.

FIGS. 6A-6D illustrate steps in a process for manufacturing the optoelectronic package of FIG. 3

FIG. 7 illustrates another implementation of the housing for the optoelectronic package.

### DETAILED DESCRIPTION

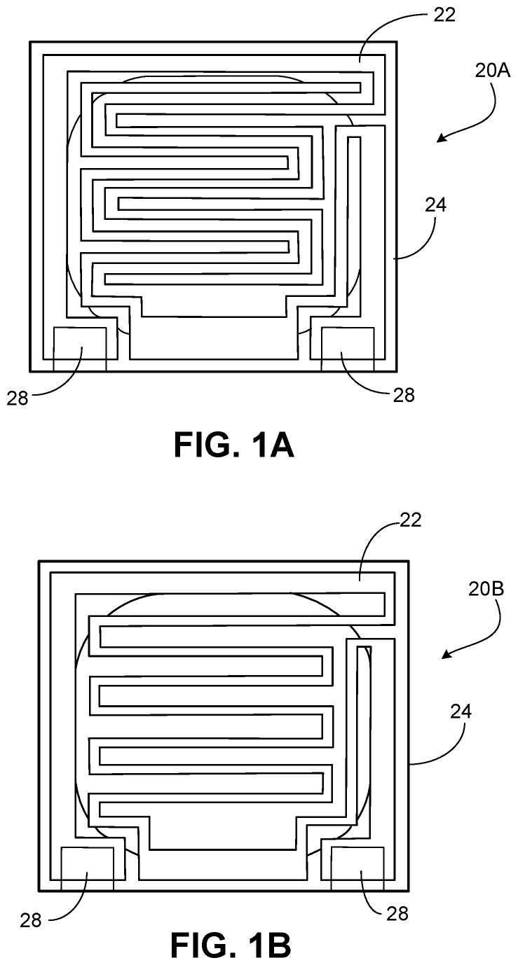

As shown in the examples of FIGS. 1A and 1B, an optical assembly 20A or 20B can be disposed over a light emitter of an illuminator or other light emitting package. To facilitate detecting mechanical defects (e.g., a crack) in the optical assembly 20A, 20B or the presence of moisture in the package, an electrically conductive structure (e.g., an electrically conductive trace) 22 can be provided on a surface of a transmissive cover (e.g., a glass substrate) 24. In some cases, the electrically conductive structure 22 is composed of a material (e.g., indium tin oxide (ITO)) that is substantially transparent to the wavelength of light produced by the light emitter (e.g., infra-red). Such electrically conductive structures thus can at least partially overlap a footprint of the optical beam emitted by the light source. In other instances, the electrically conductive structure can be composed of a material (e.g., chrome) that is substantially opaque to the wavelength of light produced by the light emitter. In such cases, the electrically conductive structure preferably does not overlap the footprint of an optical beam emitted by the light source. The electrically conductive structure 22 is connected to conductive pads 28 on the surface of the transmissive cover 24. In some instances, the electrically conductive structure 22 is covered with an insulating layer (e.g., SiO₂) having openings for the conductive pads 28, which in some cases, are composed of gold or another suitable conductive material.

The optical assembly also may include an optical component, for example, a microlens array (MLA), an optical diffuser, a lens, a refractive or diffractive optical element, a diffuser, a spectral filter, a polarizing filter, and/or some other optical structure operable to modify the optical characteristics of the output beam of the light source, which is incident on the optical assembly. In some cases, the optical assembly is operable to produce a structured-light emission.

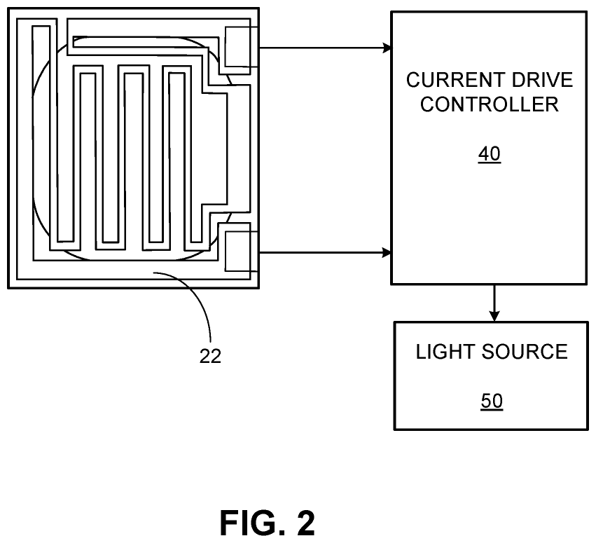

As shown in FIG. 2, the electrically conductive structure 22 can form part of an electrical circuit that is coupled to a current driver controller 40 or other electronic control unit (ECU) by way of conductive pads on the bottom of the package. The controller 40 can reside, for example, in a host device (e.g., smartphone) into which the package is integrated. The controller is operable to monitor an electrical characteristic (e.g., electrical continuity; or capacitance, using the trace of FIG. 1A; or resistance, using the trace of FIG. 1B) of the electrically conductive structure 22 such that if the monitored characteristic changes by more than a predetermined amount, the controller regulates an optical output produced by the light source. In some implementations, the controller is operable to monitor the electrical characteristic of the electrically conductive structure such that if the monitored characteristic changes by more than a respective predetermined amount, the controller causes the optical output produced by the light source to be stopped. For example, the driver can turn off the light source 50 so that it no longer emits light.

One issue addressed by the present disclosure is how to bring the signal(s) acquired at the optical assembly at the top of the package down to the electrically conductive pads (e.g., solder pads) on the bottom of the package so that the controller 40 can monitor the signal(s).

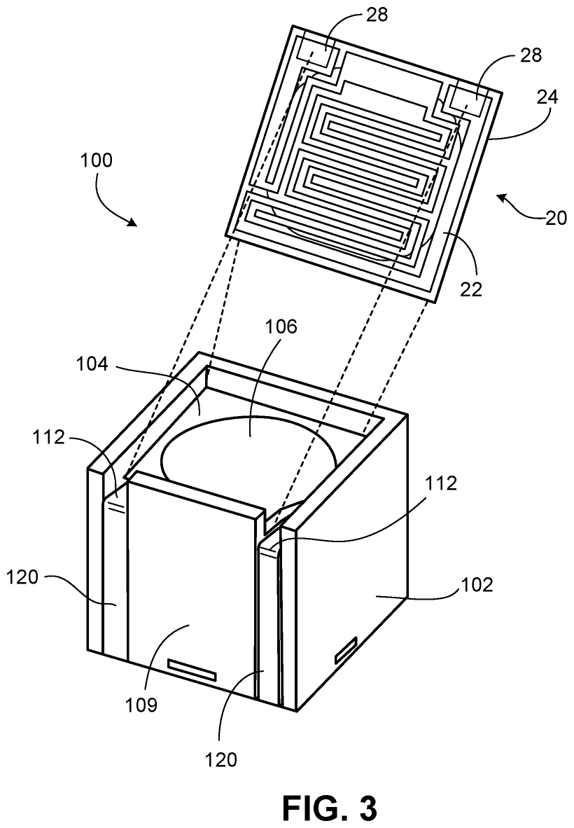

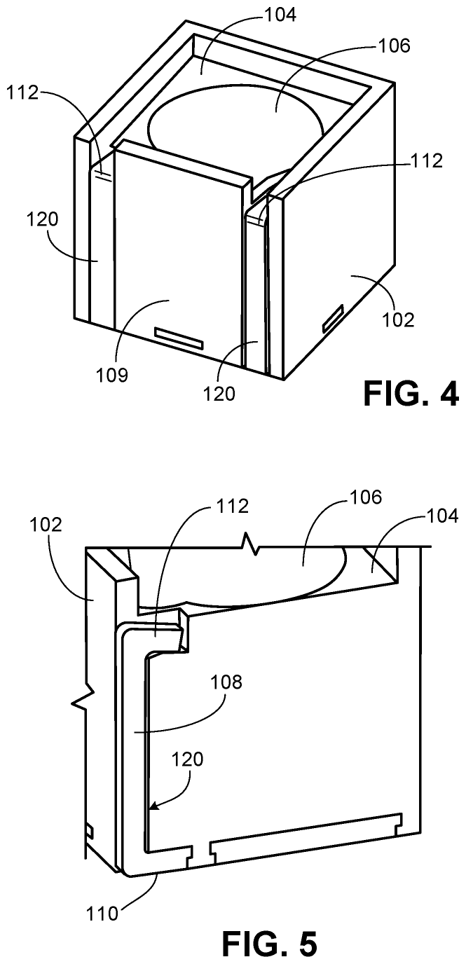

As shown in FIGS. 3, 4 and 5, a package 100 includes an electrically insulating housing 102. The housing 102 can be composed, for example, of an electrically insulating material, such as a molded epoxy (e.g., a liquid crystal polymer-based material). The top side of the housing 102 has an inner ledge 104 to support an optical assembly 20 such as the optical assembly 20A (FIG. 1A) or 20B (FIG. 1B), including the transmissive cover 24 having the trace 22 on its underside. The optical assembly 20 can be fixed to the ledge 104, for example, by a UV-cured epoxy.

The package 100 defines an inner chamber (e.g., a cavity) 106 in which the light source 50 is mounted. The light source (not shown in FIGS. 3, 4 and 5) can be implemented, for example, as a VCSEL or an array of VCSELs. Further, in some instances, the light source 50 is implemented as one or more light emitting diodes (LEDs), infra-red (IR) LEDs, organic LEDs (OLEDs), infra-red (IR) lasers, or edge-emitting laser diodes. In general, the light source is operable to emit light at a particular wavelength or within a relatively narrow wavelength range (e.g., infra-red). In some implementations, the light source is operable to generate coherent light.

In some implementations, the package 100 has four electrical contacts (e.g., solder pads) on its bottom side. Two of the contacts can be provided for the light source 50: a first contact for the light emitter's anode, a second contact for the light emitter's cathode. In addition, two contacts can be provided for electrically coupling the trace 22 to the current drive controller 40.

In order to bring the signal(s) acquired at the optical assembly 20 at the top of the package 100 down to the electrically conductive pads on the bottom of the package, the package 100 includes electrically conductive leads 120 that can be composed, at least in part, of a lead frame. A first portion 108 of each lead 120 is disposed within a respective channel in the outer surface of a sidewall 109 of the housing.

A second portion 110 of each lead 120 is bent inward at about a right angle with respect to the first portion 108 and forms a conductive contact at the bottom side of the package. The second portion 110 of the lead 120 can be coupled, for example, to the current drive controller 40.

A third portion 112 of each illustrated lead 120 also is bent inward with respect to the first portion and forms a conductive interface in electrical contact with a respective one of the conductive pads 28 on the transmissive cover 24. An electrically conductive material (e.g., silver epoxy) can be provided between each of the conductive pads 28 on the transmissive cover 24 and the third portion 112 of a respective one of the leads 120.

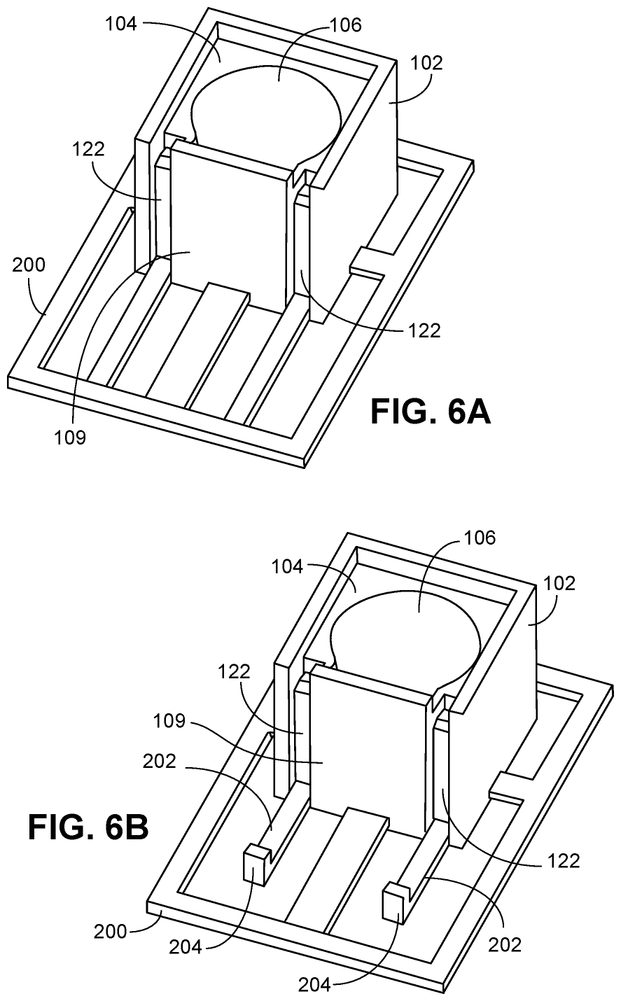

As shown in FIG. 5, in some implementations, the third portion 112 of the lead 120 is inclined slightly downward (i.e., toward the bottom-side of the package). The incline can help lock the lead 120 in place. The incline also can help facilitate manufacture of the package 20 as explained in greater detail below.

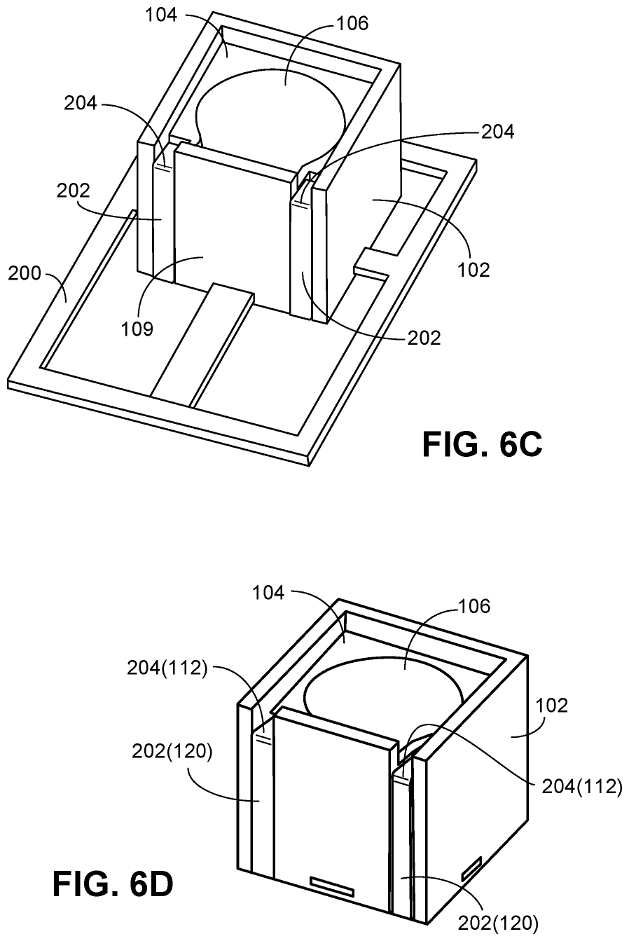

FIGS. 6A through 6D illustrate steps in the manufacture of the package 100 in accordance with some implementations. Initially, a lead frame 200 (i.e., a metal (e.g., copper) structure that can carry electrical signals) is etched and punched, and placed into a molding tool to form the housing 102 with which the lead frame 200 is integrated, as shown in FIG. 6A. The molded housing 102 defines the inner chamber 106 for the VCSEL or other light source, the ledge 104 to support the optical assembly 20, and channels 122 in the outer surface of the sidewall 109. A trim and form process then can be performed to free some of the leads 202 of the pre-molded lead frame 200 (see FIG. 6B). The free end 204 of each of the leads 202 is bent upward, as indicated in FIG. 6B. Then, as shown in FIG. 6C, the leads 202 are bent toward the housing 100 such that each of the leads 202 fits within a respective one of the channels 122 in the sidewall 109. The VCSEL or other light source can be mounted within the inner chamber 106, wire bonds can be provided for electrical connection to the light source, and the optical assembly 20 (see FIG. 3) can be fixed in place (e.g., by adhesive) on the ledge 104. The resulting package (with the optical assembly 20 omitted) is shown in FIG. 6D. In FIG. 6D, the leads 202 correspond to the leads 120 in FIGS. 3-5; likewise, the portion 204 of each lead corresponds to the portion 112 of the leads in FIGS. 3-5.

In some instances, an electrically non-conductive dual-cure adhesive that is partially curable by ultraviolet (UV) radiation and partially by heat is dispensed on the ledge 104 prior to attaching the optical assembly 20. The optical assembly 20 then can be placed on the ledge 104, and the adhesive can be cured partially with UV radiation such that the optical assembly is substantially fixed in place. Next, an electrically conductive material (e.g., an electrically conductive epoxy such as silver epoxy or other thermosetting conductive epoxy) can be dispensed between the pads 28 for the electrically conductive structure 22 on the optical assembly 20 and the electrically conductive leads 202 such that the pads 28 and the leads 202 are in electrical contact with one another. The optoelectronic package then can be subjected to a thermal treatment (e.g., a hard bake) such that the adhesive and the additional electrically conductive material are cured simultaneously. Such a configuration has the advantage that the optical assembly 20 is substantially fixed in place before subjecting the optoelectronic package to the thermal treatment, which may take place in a different location. Further, the adhesive and the additional eclectically conductive material can be prevented from intermixing by partially curing the adhesive with the UV radiation.

In some instances, the portion 204 of each lead 202 that provides the conductive interface in electrical contact with a respective one of the conductive pads 28 on the transmissive cover 24 can be configured to permit the passage of a fluid material between the inner chamber 106 and the environment outside the optoelectronic package 100.

Further, as noted above, in some instances, the portion 204 of each lead 202 can be configured to permit the passage of the additional electrically conductive material between the electrically conductive structure 22 of the optical assembly 20 and the conductive leads 202. For example, the portions 204 can be slanted or inclined downward slightly such that the additional electrically conductive material can flow more easily between the electrically conductive structure 22 and the one or more electrically conductive leads 202.

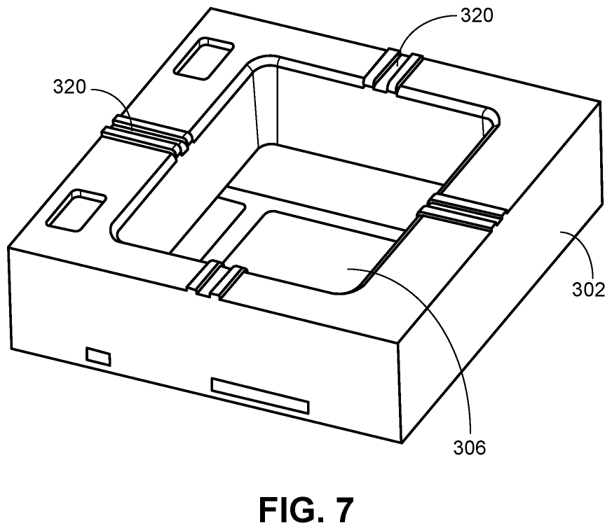

In the foregoing example of FIGS. 3-5 and 6A-6D, the leads 120 that bring the signal(s) acquired at the optical assembly at the top of the package down to the electrically conductive pads on the bottom of the package run along an outside surface of the housing sidewall 109. In other implementations, the leads can extend through a sidewall of the housing 102. An example of such a package (with the optical assembly omitted for clarity) is illustrated in FIG. 7, which shows leads 320 partially embedded within one or more sidewalls 309 of the housing 302. In this case, the leads 320 can be formed by bending portions of a lead frame into the appropriate configuration, and then attaching a mold tool to the lead frame and injecting the mold compound to form the housing 302. A VCSEL or other light source can be mounted within the inner chamber 306, wire bonds can be provided for electrical connection to the light source, and an optical assembly (e.g., 20A or 20B as shown in FIGS. 1A and 1B) can be fixed in place over the housing so that the contact pads of the optical assembly are in electrical contact with the exposed portion of the leads 320. Each lead 320 has a respective first portion extending through (and laterally surrounded by) a sidewall of the housing 302, a second portion bent with respect to the first portion and forming a conductive contact adjacent a bottom side of the housing opposite the optical assembly, and a third portion bent with respect to the first portion, the third portion of the first electrically conductive lead being adjacent the ledge which the optical assembly is supported and being in electrical contact with the electrically conductive structure (e.g., the trace) of the optical assembly. In this manner, signal(s) acquired at the optical assembly at the top of the package can be brought down to electrically conductive pads on the bottom of the package. Various other features described in connection with the example of FIGS. 3-5 and 6A-6D may be incorporated and used in connection with the example of FIG. 7 as well.

The optoelectronic packages described above can be mounted, for example, to a flex printed circuit board (PCB) for a host device such as a smart phone, object-proximity sensing device, three-dimensional imaging device, tablet computer, laptop computer, augmented reality headset, automotive vehicle, audio-visual display appliance, ambient lighting, building security monitoring system, wearable computational or data harvesting device, or networks of any of the foregoing.

Although the foregoing examples are described in connection with monitoring signals to enhance the safety of a light emitting package, the techniques described here can be used for other applications in which a signal acquired at a top side of an optical package needs to be brought to conductive pads at a bottom side of the package, or to bring signals from conductive pads at the bottom side of the package to an optical assembly at the top side of the package. Thus, for example, the present techniques can be used to apply electrical signals to an LCD screen or other active optical component on a transmissive cover, or to apply electrical signals to a heater on the transmissive cover for de-icing or for removing moisture.

Various aspects of the subject matter and the functional operations described in this specification (e.g., the current drive controller 40) can be implemented in digital electronic circuitry, or in computer software, firmware, or hardware. Thus, aspects of the subject matter described in this specification can be implemented as one or more computer program products, i.e., one or more modules of computer program instructions encoded on a computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The apparatus can include, in addition to hardware, code that creates an execution environment for the computer program in question, e.g., code that constitutes processor firmware. In some instances, the processes and logic flows can be performed by special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Computer readable media suitable for storing computer program instructions and data include all forms of non volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

While this specification contains many specifics, these should not be construed as limitations on the scope of the invention or of what may be claimed, but rather as descriptions of features specific to particular embodiments of the invention. Certain features that are described in this specification in the context of separate embodiments can also be implemented in combination in a single embodiment. Conversely, various features that are described in the context of a single embodiment also can be implemented in multiple embodiments separately or in any suitable sub-combination.

Various modifications can be made to the foregoing description within the scope and spirit of the disclosure. Accordingly, other implementations are within the scope of the claims.

1. An apparatus comprising:
an optical assembly including an electrically conductive structure;
an electrically insulating housing including:
an inner chamber;
a ledge to support the optical assembly over the inner chamber; and
a first channel extending along an outer surface of a sidewall of the housing;
a first electrically conductive lead having a first portion at least partially disposed in the first channel, a second portion bent with respect to the first portion and forming a conductive contact adjacent a bottom side of the housing opposite the optical assembly, and a third portion bent with respect to the first portion, the third portion of the first electrically conductive lead being adjacent the ledge and being in electrical contact with the electrically conductive structure.

2. The apparatus of claim 1 wherein the first electrically conductive lead is composed of a portion of a lead frame.

3. The apparatus of claim 1 wherein the electrically conductive structure is connected to the third portion of the first electrically conductive lead by way of a conductive pad of the electrically conductive structure of the optical assembly.

4. The apparatus of claim 3 wherein the electrically conductive structure further is connected to the third portion of the first electrically conductive lead by way of electrically conductive epoxy.

5. The apparatus of any one of claim 1 further including:
a light source disposed within the inner chamber;
a controller electrically coupled to the conductive contact adjacent the bottom side of the housing, the controller being operable to monitor an electrical characteristic of the electrically conductive structure, and to regulate an optical output of the light source based on the monitored electrical characteristic.

6. The apparatus of claim 5 wherein the optical assembly includes a transmissive substrate, and wherein the electrically conductive structure includes a trace on a surface of the transmissive substrate.

7. The apparatus of claim 6 wherein the electrically insulating housing includes a second channel extending along an outer surface of a sidewall of the housing, the apparatus further including a second electrically conductive lead having:
a first portion at least partially disposed in the second channel;
a second portion bent with respect to the first portion of the second electrically conductive lead and forming a second conductive contact adjacent the bottom side of the housing; and
a third portion bent with respect to the first portion of the second electrically conductive lead, the third portion of the second electrically conductive lead being adjacent the ledge and being in electrical contact with the electrically conductive structure.

8. A method comprising:
providing a lead frame;
forming an electrically insulating housing that encompasses part of the lead frame adjacent a first side of the housing, wherein the housing defines an inner chamber, a ledge adjacent a second side of the housing opposite the first side, and a channel in an outer surface of a sidewall of the housing;
trimming a first lead of the lead frame such that one end of the first lead is free;
bending the free end of the first lead;
bending the first lead toward the housing such that a first portion of the first lead fits within the channel and another portion of the first lead is adjacent the ledge; and
placing an optical assembly on the ledge such that the other portion of the first lead is in electrical contact with an electrically conductive structure of the optical assembly.

9. The method of claim 8 including:
attaching the optical assembly to the ledge using a non-conductive adhesive; and
applying UV radiation to cure the non-conductive adhesive partially.

10. The method of claim 9 including:
providing electrically conductive epoxy between the electrically conductive structure and the other portion of the first lead that is adjacent the ledge; and
applying a thermal treatment to cure the electrically conductive epoxy and to complete curing of the non-conductive adhesive.

11. The method of claim 8 wherein the optical assembly includes a transmissive substrate, and wherein the electrically conductive structure includes a trace on a surface of the transmissive substrate.

12. An apparatus comprising:
an optical assembly including an electrically conductive structure;
an electrically insulating housing including:
an inner chamber; and
a ledge to support the optical assembly over the inner chamber; and
a first electrically conductive lead having a first portion extending through a sidewall of the housing, one end of the first electrically conductive forming a conductive contact adjacent a side of the housing opposite that of the optical assembly, and a second end of the first electrically conductive lead being exposed adjacent the ledge and being in electrical contact with the electrically conductive structure.

13. The apparatus of claim 12 wherein the first electrically conductive lead is composed of a portion of a lead frame.

14. The apparatus of claim 12 wherein the electrically conductive structure is connected to the third portion of the first electrically conductive lead by way of a conductive pad of the electrically conductive structure of the optical assembly.

15. The apparatus of claim 14 wherein the electrically conductive structure further is connected to the third portion of the first electrically conductive lead by way of electrically conductive epoxy.

16. The apparatus of claim 12 further including:
a light source disposed within the inner chamber;
a controller electrically coupled to the conductive contact adjacent the bottom side of the housing, the controller being operable to monitor an electrical characteristic of the electrically conductive structure, and to regulate an optical output of the light source based on the monitored electrical characteristic.

17. The apparatus of claim 16 wherein the optical assembly includes a transmissive substrate, and wherein the electrically conductive structure includes a trace on a surface of the transmissive substrate.

18. The apparatus of claim 17 including a second electrically conductive lead having a first portion extending through a sidewall of the housing, a second portion bent with respect to the first portion of the second electrically conductive lead and forming a conductive contact adjacent the bottom side of the housing, and a third portion bent with respect to the first portion of the second electrically conductive lead, the third portion of the second electrically conductive lead being adjacent the ledge and being in electrical contact with the electrically conductive structure.

19. A method comprising:
attaching a mold tool to a lead frame having a bent portion;
injecting a mold compound into the mold tool to form an electrically insulating housing that defines an inner chamber and a ledge adjacent a first side of the housing, wherein a part of the lead frame including the bent portion forms a first electrically conductive lead having a first portion extending through a sidewall of the housing, a first end of the first electrically conductive lead forming a conductive contact adjacent a second side of the housing opposite that of the first side, and a second end of the first electrically conductive lead being exposed adjacent the ledge;
placing an optical assembly on the ledge such that the second end of the first lead is in electrical contact with an electrically conductive structure of the optical assembly.

20. The method of claim 19 wherein the optical assembly includes a transmissive substrate, and wherein the electrically conductive structure includes a trace on a surface of the transmissive substrate.
